(19) United States
(12) Patent Application Publication
(10) Pub. No.: US 2026/0180049 A1
(43) Pub. Date: Jun. 25, 2026

(54) NON-TRANSITORY COMPUTER READABLE MEDIUM STORING CONTROL PROGRAM FOR CONTROLLING SECONDARY BATTERY, CONTROL METHOD, AND CONTROL APPARATUS

(71) Applicant: TOYOTA BATTERY CO., LTD., Kosai-shi (JP)

(72) Inventor: Yuya INAGAKI, Okazaki-shi (JP)

(21) Appl. No.: 19/432,763

(22) Filed: Dec. 24, 2025

(30) Foreign Application Priority Data
Dec. 25, 2024 (JP) 2024-229486

(51) Int. Cl. H01M 10/44; G01R 31/367; G01R 31/388; H01M 10/48

(52) U.S. Cl. CPC H01M 10/443; G01R 31/367; G01R 31/388; H01M 10/486

(57) ABSTRACT

A control program according to the present disclosure causes a computer to execute: upper limit voltage setting processing for setting, a potential difference between the positive electrode open circuit potential curve and the negative electrode open circuit potential curve at a point corresponding to a state of charge at which an electrical characteristic in which deterioration rates of both a positive electrode and a negative electrode are reduced is obtained as an upper limit voltage; and lower limit voltage setting processing for setting, a potential difference between the positive electrode open circuit potential curve and the negative electrode open circuit potential curve at a point corresponding to a state of charge on a low state of charge side among states of charge at which an electrical characteristic in which deterioration rates of both the positive electrode and the negative electrode are reduced is obtained as a lower limit voltage.

### INCORPORATION BY REFERENCE

This application is based upon and claims the benefit of priority from Japanese patent application No. 2024-229486, filed on Dec. 25, 2024, the disclosure of which is incorporated herein in its entirety by reference for all purposes.

### BACKGROUND

The present disclosure relates to a non-transitory computer readable medium storing a control program for controlling a secondary battery such as a lithium ion battery, a control method, and a control apparatus.

In a secondary battery such as a lithium-ion battery, a battery is controlled in order to make the battery exhibit its performance over a long period of time while ensuring the safety of the battery. An example of a control method for controlling a secondary battery is disclosed in Japanese Patent No. 5761378.

The control apparatus disclosed in Japanese Patent No. 5761378 comprises a controller configured to control charge and discharge of a secondary battery,

wherein the controller acquires a positive electrode potential and a negative electrode potential of the secondary battery, the controller controls the charge and discharge of the secondary battery such that each of the positive electrode potential and the negative electrode potential changes within a range between an upper limit value and a lower limit value set for each of the positive electrode potential and the negative electrode potential, the controller uses a deterioration parameter to correct a local state of charge of each of a positive electrode and a negative electrode of the secondary battery and corrects an open circuit potential of each of the positive electrode and the negative electrode on the basis of the corrected local state of charge and open circuit potential characteristic data in the acquisition of the positive electrode potential and the negative electrode potential, the deterioration parameter includes a single electrode capacity ratio in the positive electrode, a single electrode capacity ratio in the negative electrode, and a variation in battery capacity of the secondary battery due to a change in correspondence between an average state of charge within an active material of the positive electrode and an average state of charge within an active material of the negative electrode, the change being a change from an initial state, and the open circuit potential characteristic data is data defining a relationship between the local state of charge at a surface of the active material of the positive electrode and the open circuit potential of the positive electrode and a relationship between the local state of charge at a surface of the active material of the negative electrode and the open circuit potential of the negative electrode.

### SUMMARY

In order to make a secondary battery exhibit its performance over a long period of time while ensuring the safety of the secondary battery, it is necessary to suppress deterioration of the secondary battery. For example, as disclosed in Japanese Patent No. 5761378, the deterioration can be suppressed by charging and discharging the secondary battery within a range in which no side reaction occurs in the electrodes. However, in Japanese Patent No. 5761378, the local state of charge s of the positive and the negative electrodes are merely corrected by using the deterioration parameter, and the use conditions (e.g., upper and lower limit voltages of an output voltage) of the battery are not limited, and hence there is a problem that the deterioration cannot be effectively suppressed.

The present disclosure has been made in view of the above-described circumstances, and an object thereof is to make a secondary battery exhibit its performance over a long period of time while ensuring the safety of the secondary battery.

In an aspect of a non-transitory computer readable medium storing a control program for controlling a secondary battery according to the present disclosure, the control program causes a computer to execute: measurement processing for acquiring an output voltage, charging and discharging currents, and a battery temperature of a secondary battery to be controlled; adaptation processing for inputting the output voltage, the charging and discharging currents, and the battery temperature and then adapting a state estimation model configured to estimate a state of charge of the secondary battery to an actual state of the secondary battery; positive electrode estimation processing for estimating a capacity deterioration and a state of charge of a positive electrode by using the state estimation model; negative electrode estimation processing for estimating a capacity deterioration and a state of charge of a negative electrode by using the state estimation model; fitting processing for fitting a positive electrode open circuit potential curve and a negative electrode open circuit potential curve to a current state by using a positive electrode corresponding point on the positive electrode and a negative electrode corresponding point on the negative electrode which correspond to the state of charge s estimated using the state estimation model; upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as an upper limit voltage during charging and discharging of the secondary battery; and lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among state of charge s at which an electrical characteristic in which deterioration rates of both the positive electrode and the negative electrode are reduced is obtained as a lower limit voltage during charging and discharging of the secondary battery.

An aspect of a control method for controlling a secondary battery according to the present disclosure is a control method automatically executed by a computer, in which the control method includes: measurement processing for acquiring an output voltage, charging and discharging currents, and a battery temperature of a secondary battery to be controlled; adaptation processing for inputting the output voltage, the charging and discharging currents, and the battery temperature and then adapting a state estimation model configured to estimate a state of charge of the secondary battery to an actual state of the secondary battery; positive electrode estimation processing for estimating a capacity deterioration and a state of charge of a positive electrode by using the state estimation model; negative electrode estimation processing for estimating a capacity deterioration and a state of charge of a negative electrode by using the state estimation model; fitting processing for fitting a positive electrode open circuit potential curve and a negative electrode open circuit potential curve to a current state by using a positive electrode corresponding point on the positive electrode and a negative electrode corresponding point on the negative electrode which correspond to the state of charge s estimated using the state estimation model; upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as an upper limit voltage during charging and discharging of the secondary battery; and lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among state of charge s at which an electrical characteristic in which deterioration rates of both the positive electrode and the negative electrode are reduced is obtained as a lower limit voltage during charging and discharging of the secondary battery.

An aspect of a control apparatus configured to control a secondary battery according to the present disclosure is a control apparatus configured to control charging and discharging of a secondary battery, in which the control apparatus includes: a memory configured to store data and a program; and an arithmetic unit configured to execute the program, to thereby execute processing for setting an upper limit voltage and a lower limit voltage during charging and discharging of the secondary battery, and the arithmetic unit is configured to execute: measurement processing for acquiring an output voltage, charging and discharging currents, and a battery temperature of a secondary battery to be controlled; adaptation processing for inputting the output voltage, the charging and discharging currents, and the battery temperature and then adapting a state estimation model configured to estimate a state of charge of the secondary battery to an actual state of the secondary battery; positive electrode estimation processing for estimating a capacity deterioration and a state of charge of a positive electrode by using the state estimation model; negative electrode estimation processing for estimating a capacity deterioration and a state of charge of a negative electrode by using the state estimation model; fitting processing for fitting a positive electrode open circuit potential curve and a negative electrode open circuit potential curve to a current state by using a positive electrode corresponding point on the positive electrode and a negative electrode corresponding point on the negative electrode which correspond to the state of charge s estimated using the state estimation model; upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as the upper limit voltage during charging and discharging of the secondary battery; and lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among state of charge s at which an electrical characteristic in which deterioration rates of both the positive electrode and the negative electrode are reduced is obtained as the lower limit voltage during charging and discharging of the secondary battery.

By the control program, the control method, and the control apparatus for controlling a secondary battery according to the present disclosure, it is possible to make a secondary battery exhibit its performance over a long period of time while ensuring the safety of the secondary battery.

The above and other objects, features and advantages of the present disclosure will become more fully understood from the detailed description given hereinbelow and the accompanying drawings.

### BRIEF DESCRIPTION OF DRAWINGS

FIG. 1 is a graph for explaining SOC-OCP curves for explaining an outline of a control method for controlling a secondary battery according to a first embodiment;

FIG. 2 is a flowchart for explaining a flow of deterioration suppression processing performed in the control method for controlling a secondary battery according to the first embodiment;

FIG. 3 is a flowchart for explaining a flow of upper limit voltage setting processing performed in the control method for controlling a secondary battery according to the first embodiment;

FIG. 4 is a flowchart for explaining a flow of lower limit voltage setting processing performed in the control method for controlling a secondary battery according to the first embodiment; and

FIG. 5 is a diagram for explaining first to fourth voltages calculated in the upper limit voltage setting processing and the lower limit voltage setting processing according to the first embodiment.

### DESCRIPTION OF EMBODIMENTS

For the clarification of the description, the following descriptions and the drawings are partially omitted and simplified as appropriate. Further, elements described in the drawings as functional blocks which perform various types of processing may be configured as regards hardware by a Central Processing Unit (CPU), a memory, and other circuits, and are implemented as regards software by a program etc. loaded in the memory. Therefore, it will be understood by those skilled in the art that these functional blocks may be implemented in various forms such as hardware only, software only, or a combination thereof, and the present disclosure is not limited to any of them. Note that the same elements are denoted by the same reference numerals or symbols throughout the drawings, and redundant descriptions are omitted as necessary.

Further, the above-described program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a Random-Access Memory (RAM), a Read-Only Memory (ROM), a flash memory, a Solid-State Drive (SSD) or other types of memory technologies, a CD-ROM, a Digital Versatile Disc (DVD), a Blu-ray (Registered Trademark) disc or other types of optical disc storage, a magnetic cassette, a magnetic tape, and a magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

### First Embodiment

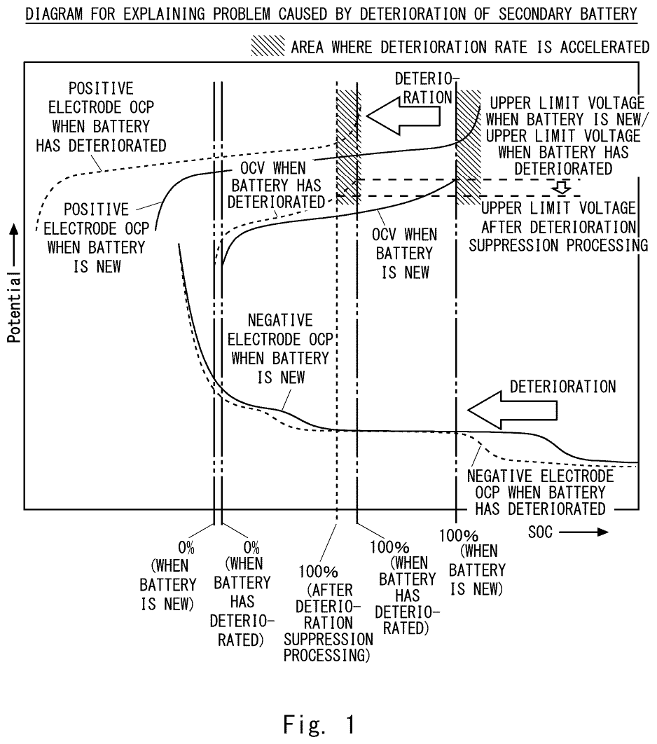

A control apparatus which controls a secondary battery according to a first embodiment maintains the performance of a secondary battery safely and over a long period of time by performing deterioration suppression processing. FIG. 1 shows a graph for explaining a relationship between a state of charge and open circuit potential curves of positive and negative electrodes (SOC-OCP curves) for explaining an outline of a control method for controlling a secondary battery according to the first embodiment. FIG. 1 is a diagram for explaining a problem caused by the deterioration of a secondary battery. Further, in the deterioration suppression processing, an upper limit voltage and a lower limit voltage during charging and discharging of a secondary battery are updated in accordance with a deterioration state of the secondary battery. FIG. 1 shows SOC-OCV curves superimposed on the SOC-OCP curves. The SOC-OCV curve is a reference value and shows a relationship between a state of charge and an open circuit voltage of an output voltage of the secondary battery.

As shown in FIG. 1, an open circuit voltage (OCV) of the secondary battery changes in accordance with the change in the state of charge. This change occurs because the potential of the positive electrode and the potential of the negative electrode change due to a charging and discharging operation. In the secondary battery, the difference between the potential of the positive electrode and the potential of the negative electrode is the open circuit voltage generated between a positive electrode terminal and a negative electrode terminal. The potential of the positive electrode and the potential of the negative electrode described above can be measured as an open circuit potential (OCP) of a positive electrode (hereinafter referred to as a positive electrode OCP) and an OCP of a negative electrode (hereinafter referred to as a negative electrode OCP), respectively. Further, the positive electrode OCP and the negative electrode OCP can be logically derived from an active material included in a composite with which each of the electrodes is coated.

Further, as shown in FIG. 1, the positive electrode OCP extends to an area where the state of charge (i.e., state of charge (SOC)) is 0% or less. This indicates that the state of charge of 0% indicates that the negative electrode is in a state where an acceptable amount of lithium is exceeded, and that lithium that can be released to the positive electrode side remains even when the state of charge becomes 0%. Further, in FIG. 1, the negative electrode OCP extends to an area in which the state of charge is 100% or more. This indicates that the state of charge of 100% indicates that the positive electrode is in a state where an acceptable amount of lithium is exceeded, and that lithium that can be released to the negative electrode side remains even when the state of charge becomes 100%.

Further, when the secondary battery deteriorates, the positive electrode OCP shifts leftward to a side in which the state of charge becomes lower or the positive electrode capacity itself decreases, and the negative electrode OCP shifts rightward or the negative electrode capacity itself decreases. Due to the above changes in the positive electrode OCP and the negative electrode OCP, the range in which the state of charge becomes 0% to 100% becomes narrow. At this time, if the upper limit voltage and the lower limit voltage set with regard to the output voltage of the secondary battery are not changed in the charging and discharging operation of the secondary battery, the range of the open circuit potential in which the deterioration rate of the secondary battery is accelerated is used, and thus a problem that the deterioration of the secondary battery is accelerated occurs. In FIG. 1, the difference between the case in which the deterioration suppression processing is applied to the upper limit voltage and the case in which the deterioration suppression processing is not applied to the upper limit voltage is only shown. However, the deterioration suppression processing is also applied to the lower limit voltage. In the deterioration suppression processing according to the first embodiment, in terms of the positive electrode OCP and the negative electrode OCP, the upper limit voltage and the lower limit voltage that can avoid the use of the area where the deterioration rate is accelerated are set.

Note that the deterioration of the positive electrode and the negative electrode means, for example, the occurrence of overcharging or overdischarging of the secondary battery, which causes side reactions such as lithium deposition and disintegration of a positive electrode active material in each of the electrodes of the secondary battery, resulting in a decrease in performance such as an increase in battery resistance and a decrease in capacity.

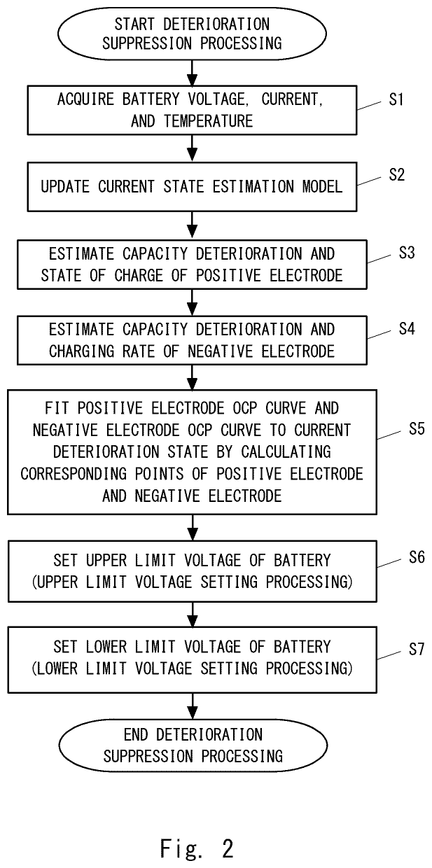

FIG. 2 is a flowchart for explaining a flow of the deterioration suppression processing performed in the control method for controlling a secondary battery according to the first embodiment. The deterioration suppression processing shown in FIG. 2 is implemented, for example, by executing a control program for implementing the deterioration suppression processing in a control apparatus which controls charging and discharging of the secondary battery. The control apparatus includes, for example, a memory which stores data and a program, and an arithmetic unit which executes the control program, thereby performing the deterioration suppression processing for setting the upper limit voltage and the lower limit voltage during charging and discharging of the secondary battery. That is, the control method for controlling a secondary battery according to the first embodiment is implemented by a computer automatically executing the control program for performing the deterioration suppression processing.

As shown in FIG. 2, in the deterioration suppression processing according to the first embodiment, first, measurement processing for acquiring an output voltage, charging and discharging currents, and a battery temperature of the secondary battery to be controlled is performed (Step S1). Next, adaptation processing for inputting the output voltage, the charging and discharging currents, and the battery temperature and then adapting a state estimation model which estimates the state of charge (i.e., state of charge (SOC)) of the secondary battery to the actual state of the secondary battery is performed (Step S2). By the above processing of Steps S1 and S2, the state estimation model held in the control apparatus is updated to a model capable of calculating the actual internal state of the secondary battery.

After that, in the deterioration suppression processing according to the first embodiment, positive electrode estimation processing (Step S3) for estimating the capacity deterioration and the state of charge of the positive electrode by using the state estimation model and negative electrode estimation processing (Step S4) for estimating the capacity deterioration and the state of charge of the negative electrode by using the state estimation model are performed. Further, in the deterioration suppression processing, fitting processing (Step S5) for fitting a positive electrode open circuit potential curve (a positive electrode OCP curve) and a negative electrode open circuit potential curve (a negative electrode OCP curve) to the current state by using a positive electrode corresponding point on the positive electrode and a negative electrode corresponding point on the negative electrode which correspond to the state of charge s estimated using the state estimation model is performed. By the above processing of Steps S3 to S5, the capacity deviation and the decrease in a single electrode capacity (a positive electrode capacity or a negative electrode capacity) caused by the deterioration of the secondary battery are corrected.

Next, in the deterioration suppression processing according to the first embodiment, upper limit voltage setting processing (Step S6) and lower limit voltage setting processing (Step S7) are performed. In the upper limit voltage setting processing (Step S6), in the positive electrode open circuit potential curve (the positive electrode OCP curve) and the negative electrode open circuit potential curve (the negative electrode OCP curve) after the fitting processing (Step S5), the potential difference between the positive electrode OCP curve and the negative electrode OCP curve at a point corresponding to a state of charge at which an electrical characteristic in which deterioration rates of both the positive electrode and the negative electrode are reduced is obtained is set as the upper limit voltage during charging and discharging of the secondary battery. In the lower limit voltage setting processing (Step S7), in the positive electrode OCP curve and the negative electrode OCP curve after the fitting processing (Step S5), the potential difference between the positive electrode OCP curve and the negative electrode OCP curve at a point corresponding to a state of charge on a low state of charge side among state of charge s at which an electrical characteristic in which deterioration rates of both the positive electrode and the negative electrode are reduced is obtained is set as the lower limit voltage during charging and discharging of the secondary battery. The upper limit voltage setting processing and the lower limit voltage setting processing described above will be described in more detail below.

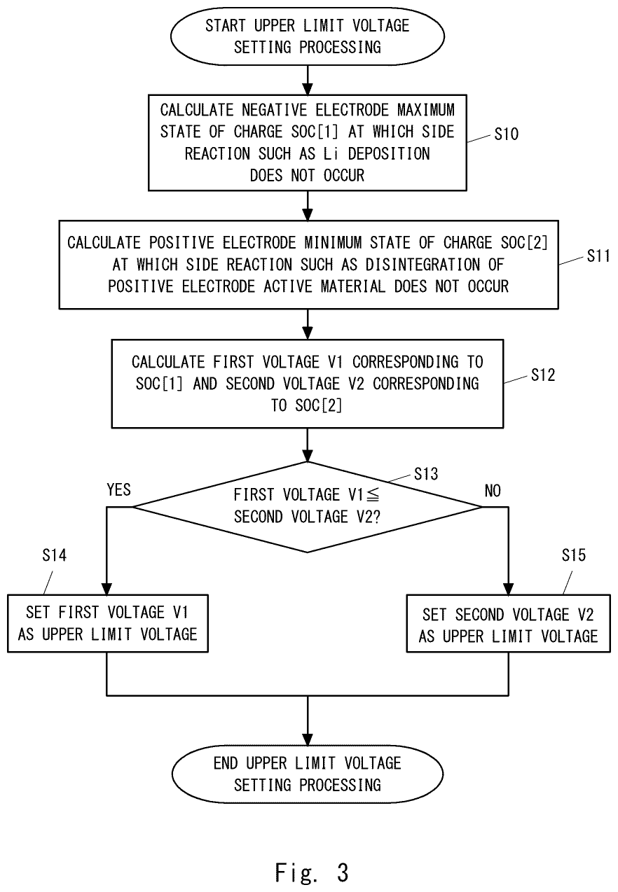

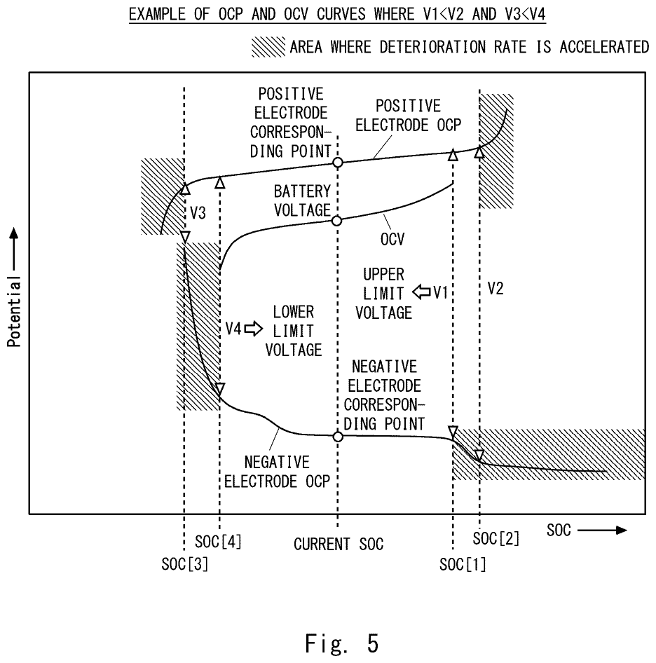

FIG. 3 is a flowchart for explaining a flow of the upper limit voltage setting processing performed in the control method for controlling a secondary battery according to the first embodiment. Further, FIG. 5 is a diagram for explaining first to fourth voltages calculated in the upper limit voltage setting processing and the lower limit voltage setting processing according to the first embodiment. The upper limit voltage setting processing will be described below with reference to FIG. 3 while referring to FIG. 5 as appropriate. Note that FIG. 5 shows the OCV curve, the positive electrode OCP curve, and the negative electrode OCP curve of the secondary battery at a certain point of time as an example, and shows a state in which a first voltage V1 described later is smaller than a second voltage V2 and a third voltage V3 is smaller than a fourth voltage V4.

As shown in FIG. 3, in the upper limit voltage setting processing, first, state of charge s at which no side reaction occurs in the negative electrode and the positive electrode in an area (i.e., an area where overcharging occurs) on the high state of charge side are calculated. In this area, lithium deposition is at least considered as a side reaction in the negative electrode. Further, in the positive electrode, disintegration of the positive electrode active material is at least considered as a side reaction. Therefore, in the upper limit voltage setting processing, negative electrode maximum state of charge calculation processing for calculating a negative electrode maximum state of charge SOC[1] at which at least lithium deposition does not occur as a side reaction in the negative electrode is performed (Step S10). Further, in the upper limit voltage setting processing, positive electrode minimum state of charge calculation processing for calculating a positive electrode minimum state of charge SOC[2] at which at least disintegration of the positive electrode active material does not occur as a side reaction in the positive electrode is performed (Step S11).

Next, in the upper limit voltage setting processing, high state of charge side potential difference calculation processing for calculating a potential difference between the positive electrode OCP curve and the negative electrode OCP curve at the negative electrode maximum state of charge SOC[1] as the first voltage V1, and calculating a potential difference between the positive electrode OCP curve and the negative electrode OCP curve at the positive electrode minimum state of charge SOC[2] as the second voltage V2 is performed (Step S12). Then, in the upper limit voltage setting processing, upper limit voltage update processing for updating the upper limit voltage with the first voltage V1 if the first voltage V1 is equal to or less than the second voltage V2 (YES in Step S13) (Step S14), and updating the upper limit voltage with the second voltage V2 if the first voltage V1 is larger than the second voltage V2 (NO in Step S13) (Step S15) is performed.

The first voltage V1 and the second voltage V2 calculated in the high state of charge side potential difference calculation processing (Step S12) will be described below with reference to FIG. 5. As shown in FIG. 5, the area where the deterioration rate of the negative electrode is accelerated corresponds to the area where the state of charge is higher than the inflection point of the negative electrode OCP curve. For example, in the negative electrode, when lithium deposition starts, the resistance of the negative electrode increases rapidly, so that an inflection point occurs in the negative electrode OCP curve. Therefore, in the negative electrode maximum state of charge calculation processing in Step S10, the state of charge corresponding to the inflection point of the negative electrode OCP curve is set as the negative electrode maximum state of charge SOC[1]. Then, in the high state of charge side potential difference calculation processing in Step S12, the potential difference between the positive electrode OCP curve and the negative electrode OCP curve at the negative electrode maximum state of charge SOC[1] is set as the first voltage V1.

Further, as shown in FIG. 5, the area where the deterioration rate of the positive electrode is accelerated corresponds to the area where the state of charge is higher than the inflection point of the positive electrode OCP curve. For example, in the positive electrode, when the positive electrode active material starts to disintegrate, the resistance of the positive electrode increases rapidly, so that an inflection point occurs in the positive electrode OCP curve. Therefore, in the positive electrode minimum state of charge calculation processing in Step S11, the state of charge corresponding to the inflection point of the positive electrode OCP curve is set as the positive electrode minimum state of charge SOC[2]. Then, in the high state of charge side potential difference calculation processing in Step S12, the potential difference between the positive electrode OCP curve and the negative electrode OCP curve at the positive electrode minimum state of charge SOC[2] is set as the second voltage V2. Then, in the example shown in FIG. 5, since the first voltage V1 is smaller than the second voltage V2, the first voltage V1 is set as the upper limit voltage.

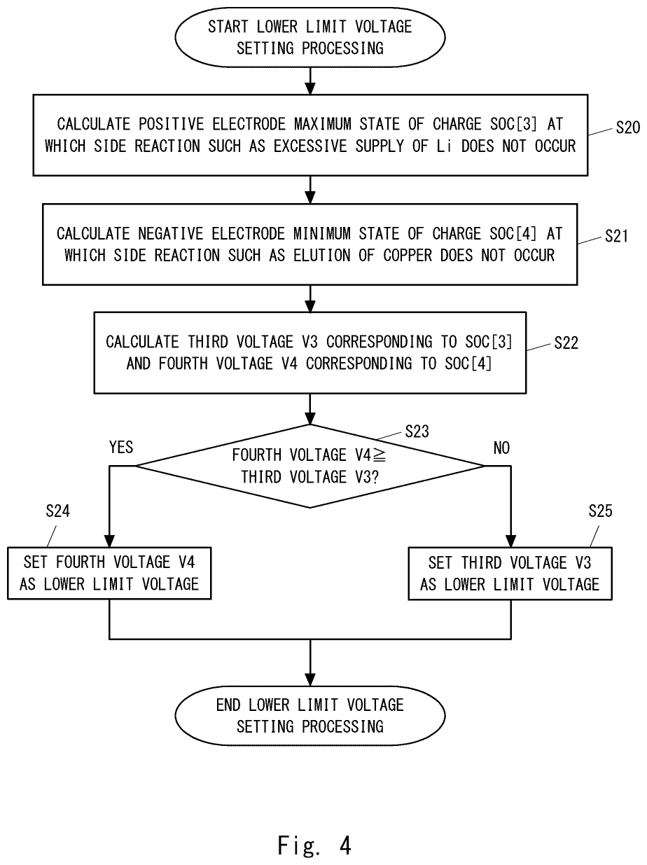

Next, FIG. 4 shows a flowchart for explaining a flow of the lower limit voltage setting processing performed in the control method for controlling a secondary battery according to the first embodiment. The lower limit voltage setting processing will be described below with reference to FIG. 4 while referring to FIG. 5 as appropriate.

As shown in FIG. 4, in the lower limit voltage setting processing, first, state of charge s at which no side reaction occurs in the positive electrode and the negative electrode in an area (i.e., an area where overdischarging occurs) on the low state of charge side are calculated. In this area, excessive supply of lithium is at least considered as a side reaction in the positive electrode. Further, in the negative electrode, elution of copper is at least considered as a side reaction. Therefore, in the lower limit voltage setting processing, positive electrode maximum state of charge calculation processing for calculating a positive electrode maximum state of charge SOC[3] at which at least excessive supply of lithium does not occur as a side reaction in the positive electrode is performed (Step S20). Further, in the lower limit voltage setting processing, negative electrode minimum state of charge calculation processing for calculating a negative electrode minimum state of charge SOC[4] at which at least elution of copper does not occur as a side reaction in the negative electrode is performed (Step S21).

Next, in the lower limit voltage setting processing, low state of charge side potential difference calculation processing for calculating a potential difference between the positive electrode OCP curve and the negative electrode OCP curve at the positive electrode maximum state of charge SOC[3] as the third voltage V3, and calculating a potential difference between the positive electrode OCP curve and the negative electrode OCP curve at the negative electrode minimum state of charge SOC[4] as the fourth voltage V4 is performed (Step S22). Then, in the lower limit voltage setting processing, lower limit voltage update processing for updating the lower limit voltage with the fourth voltage V4 if the third voltage V3 is smaller than the fourth voltage V4 (YES in Step S23) (Step S24), and updating the lower limit voltage with the third voltage V3 if the third voltage V3 is equal to or smaller than the fourth voltage V4 (NO in Step S23) (Step S25) is performed.

The third voltage V3 and the fourth voltage V4 calculated in the low state of charge side potential difference calculation processing (Step S22) will be described below with reference to FIG. 5. As shown in FIG. 5, the area where the deterioration rate of the positive electrode is accelerated corresponds to the area where the state of charge is lower than the inflection point of the positive electrode OCP curve. For example, in the positive electrode, when excessive supply of lithium starts, the resistance of the positive electrode decreases rapidly, so that an inflection point occurs in the positive electrode OCP curve. Therefore, in the positive electrode maximum state of charge calculation processing in Step S20, the state of charge corresponding to the inflection point of the positive electrode OCP curve is set as the positive electrode maximum state of charge SOC[3]. Then, in the low state of charge side potential difference calculation processing in Step S22, the potential difference between the positive electrode OCP curve and the negative electrode OCP curve at the positive electrode maximum state of charge SOC[3] is set as the third voltage V3.

Further, as shown in FIG. 5, the area where the deterioration rate of the negative electrode is accelerated corresponds to the area where the state of charge is lower than the inflection point of the negative electrode OCP curve. For example, in the negative electrode, when the elution of copper starts, the resistance of the negative electrode decreases rapidly, so that an inflection point occurs in the negative electrode OCP curve. Therefore, in the negative electrode minimum state of charge calculation processing in Step S21, the state of charge corresponding to the inflection point of the negative electrode OCP curve is set as the negative electrode minimum state of charge SOC[4]. Then, in the high state of charge side potential difference calculation processing in Step S22, the potential difference between the positive electrode OCP curve and the negative electrode OCP curve at the negative electrode minimum state of charge SOC[4] is set as the fourth voltage V4. Then, in the example shown in FIG. 5, since the third voltage V3 is larger than the fourth voltage V4, the fourth voltage V4 is set as the lower limit voltage.

As described above, in the control method including the deterioration suppression processing according to the first embodiment, the output voltage of a secondary battery during charging and discharging is limited by upper and lower limit voltages that avoid an area where the deterioration rate of the secondary battery is accelerated by using a state estimation model while updating the state estimation model. Thus, by applying the control method according to the first embodiment, it is possible to continuously suppress the deterioration of the secondary battery. Further, when the control method according to the first embodiment is applied, it is possible to maximize the use area of the secondary battery in consideration of the deterioration state of the battery. That is, by applying the control method according to the first embodiment, it is possible to make the secondary battery exhibit its performance as much as possible while ensuring the safety of the secondary battery and suppressing the deterioration of the same.

Note that the present disclosure is not limited to the above-described embodiments and may be changed as appropriate without departing from the scope and sprit of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A non-transitory computer readable medium storing a control program for controlling a secondary battery, the control program causing a computer to execute:
measurement processing for acquiring an output voltage, charging and discharging currents, and a battery temperature of the secondary battery to be controlled;
adaptation processing for inputting the output voltage, the charging and discharging currents, and the battery temperature and then adapting a state estimation model configured to estimate a state of charge of the secondary battery to an actual state of the secondary battery;
positive electrode estimation processing for estimating a capacity deterioration and a state of charge of a positive electrode by using the state estimation model;
negative electrode estimation processing for estimating a capacity deterioration and a state of charge of a negative electrode by using the state estimation model;
fitting processing for fitting a positive electrode open circuit potential curve and a negative electrode open circuit potential curve to a current state by using a positive electrode corresponding point on the positive electrode and a negative electrode corresponding point on the negative electrode which correspond to the states of charge estimated using the state estimation model;
upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as an upper limit voltage during charging and discharging of the secondary battery; and
lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among states of charge at which an electrical characteristic in which deterioration rates of both the positive electrode and the negative electrode are reduced is obtained as a lower limit voltage during charging and discharging of the secondary battery.

2. The non-transitory computer readable medium according to claim 1, wherein the upper limit voltage setting processing comprises:
negative electrode maximum state of charge calculation processing for calculating a negative electrode maximum state of charge at which no side reaction occurs in the negative electrode;
positive electrode minimum state of charge calculation processing for calculating a positive electrode minimum state of charge at which no side reaction occurs in the positive electrode;
high state of charge side potential difference calculation processing for calculating a potential difference between the positive electrode open circuit potential curve and the negative electrode open circuit potential curve at the negative electrode maximum state of charge as a first voltage, and calculating a potential difference between the positive electrode open circuit potential curve and the negative electrode open circuit potential curve at the positive electrode minimum state of charge as a second voltage; and
upper limit voltage update processing for updating the upper limit voltage with the first voltage if the first voltage is equal to or less than the second voltage, and updating the upper limit voltage with the second voltage if the first voltage is larger than the second voltage.

3. The non-transitory computer readable medium according to claim 1, wherein the lower limit voltage setting processing comprises:
positive electrode maximum state of charge calculation processing for calculating a positive electrode maximum state of charge at which no side reaction occurs in the positive electrode;
negative electrode minimum state of charge calculation processing for calculating a negative electrode minimum state of charge at which no side reaction occurs in the negative electrode;
low state of charge side potential difference calculation processing for calculating a potential difference between the positive electrode open circuit potential curve and the negative electrode open circuit potential curve at the positive electrode maximum state of charge as a third voltage, and calculating a potential difference between the positive electrode open circuit potential curve and the negative electrode open circuit potential curve at the negative electrode minimum state of charge as a fourth voltage; and
lower limit voltage update processing for updating the lower limit voltage with the fourth voltage if the third voltage is equal to or less than the fourth voltage, and updating the lower limit voltage with the third voltage if the third voltage is larger than the fourth voltage.

4. A control method for controlling a secondary battery, the control method being automatically executed by a computer, wherein the control method comprises:
measurement processing for acquiring an output voltage, charging and discharging currents, and a battery temperature of the secondary battery to be controlled;
adaptation processing for inputting the output voltage, the charging and discharging currents, and the battery temperature and then adapting a state estimation model configured to estimate a state of charge of the secondary battery to an actual state of the secondary battery;
positive electrode estimation processing for estimating a capacity deterioration and a state of charge of a positive electrode by using the state estimation model;
negative electrode estimation processing for estimating a capacity deterioration and a state of charge of a negative electrode by using the state estimation model;
fitting processing for fitting a positive electrode open circuit potential curve and a negative electrode open circuit potential curve to a current state by using a positive electrode corresponding point on the positive electrode and a negative electrode corresponding point on the negative electrode which correspond to the states of charge estimated using the state estimation model;
upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as an upper limit voltage during charging and discharging of the secondary battery; and
lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among states of charge at which an electrical characteristic in which deterioration rates of both the positive electrode and the negative electrode are reduced is obtained as a lower limit voltage during charging and discharging of the secondary battery.

5. A control apparatus configured to control charging and discharging of a secondary battery,
wherein the control apparatus comprises:
a memory configured to store data and a program; and
an arithmetic unit configured to execute the program, to thereby execute processing for setting an upper limit voltage and a lower limit voltage during charging and discharging of the secondary battery,
wherein the arithmetic unit is configured to execute:
measurement processing for acquiring an output voltage, charging and discharging currents, and a battery temperature of the secondary battery to be controlled;
adaptation processing for inputting the output voltage, the charging and discharging currents, and the battery temperature and then adapting a state estimation model configured to estimate a state of charge of the secondary battery to an actual state of the secondary battery;
positive electrode estimation processing for estimating a capacity deterioration and a state of charge of a positive electrode by using the state estimation model;
negative electrode estimation processing for estimating a capacity deterioration and a state of charge of a negative electrode by using the state estimation model;
fitting processing for fitting a positive electrode open circuit potential curve and a negative electrode open circuit potential curve to a current state by using a positive electrode corresponding point on the positive electrode and a negative electrode corresponding point on the negative electrode which correspond to the states of charge estimated using the state estimation model;
upper limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge at which an electrical characteristic in which deterioration rates of both the positive electrode and the negative electrode are reduced is obtained as the upper limit voltage during charging and discharging of the secondary battery; and
lower limit voltage setting processing for setting, in the positive electrode open circuit potential curve and the negative electrode open circuit potential curve after the fitting processing, a potential difference between the positive electrode open circuit potential curve and the negative electrode open circuit potential curve at a point corresponding to a state of charge on a low state of charge side among states of charge at which an electrical characteristic in which deterioration rates of both the positive electrode and the negative electrode are reduced is obtained as the lower limit voltage during charging and discharging of the secondary battery.
